(19) United States
(12) Patent Application Publication
(10) Pub. No.: US 2023/0089928 A1
(43) Pub. Date: Mar. 23, 2023

(54) SEMICONDUCTOR DEVICES HAVING HOLLOW FILLER MATERIALS

(71) Applicants: Ziyin Lin, Chandler, AZ (US); Yiqun Bai, Chandler, AZ (US); Hongxia Feng, Chandler, AZ (US); Dingying Xu, Chandler, AZ (US); Jieying Kong, Chandler, AZ (US); Srinivas Pietambaram, Chandler, AZ (US)

(72) Inventors: Ziyin Lin, Chandler, AZ (US); Yiqun Bai, Chandler, AZ (US); Hongxia Feng, Chandler, AZ (US); Dingying Xu, Chandler, AZ (US); Jieying Kong, Chandler, AZ (US); Srinivas Pietambaram, Chandler, AZ (US)

(21) Appl. No.: 17/482,351

(22) Filed: Sep. 22, 2021

(51) Int. Cl. H01L 23/31; H01L 23/18; H01L 23/29; H01L 23/538; H01L 23/00; H01L 21/56

(52) U.S. Cl. CPC H01L 23/31; H01L 23/18; H01L 23/295; H01L 23/5381; H01L 23/562; H01L 21/56

(57) ABSTRACT

Semiconductor devices having hollow filler materials are disclosed. A disclosed example semiconductor device includes at least one of a substrate or an interposer, interconnects extending through the at least one of the substrate or the interposer, and a composite material integral with or covering at least a portion of the semiconductor device, the composite material including a polymer matrix with a hollow filler material having voids therein.

### FIELD OF THE DISCLOSURE

This disclosure relates generally to semiconductor devices and, more particularly, to semiconductor devices having hollow filler materials.

### BACKGROUND

Encapsulation materials are typically used on semiconductor devices. In particular, the encapsulation materials can be implemented to reduce warpage and exposure to external elements, and, thus, reduce damage of a semiconductor device. Some known encapsulation materials are embedded with filler, additives or a polymer resin to vary and/or control overall characteristics of the encapsulation materials.

### BRIEF DESCRIPTION OF THE DRAWINGS

FIG. 1 is a cross-sectional cutaway view of an example semiconductor device with hollow filler material in accordance with teachings of this disclosure.

FIG. 2 is a detailed view of a region of the example semiconductor device shown in FIG. 1.

FIGS. 3A-3G depict example implementations in accordance with teachings of this disclosure.

FIG. 4 is a flowchart representative of an example method to produce examples disclosed herein.

The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular. In general, the same reference numbers will be used throughout the drawing(s) and accompanying written description to refer to the same or like parts. As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another. Notwithstanding the foregoing, in the case of a semiconductor device, “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component. As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween. As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name. As used herein, “approximately” and “about” refer to dimensions that may not be exact due to manufacturing tolerances and/or other real world imperfections.

### DETAILED DESCRIPTION

Semiconductor devices having hollow filler materials are disclosed. Some known semiconductor devices utilize encapsulation materials for protection thereof from an environment, foreign materials and/or operating conditions. These encapsulation materials can also be implemented to reduce warpage of a semiconductor device. Typically, the encapsulation materials can be embedded with filler, additives or a polymer resin to adjust operational characteristics of the encapsulation materials with the semiconductor device. However, these known encapsulation materials can have a relatively high modulus of elasticity and, thus, can subject a component and/or device to excess warping and/or damage.

Examples disclosed herein enable semiconductor devices that are highly robust and able to withstand forces and/or warpage effectively, thereby increasing device reliability. Examples disclosed herein can have a similar coefficient of thermal expansion (CTE) to bulk polymers while still exhibiting a much greater resistance to damage than known implementations. Examples disclosed herein utilize a composite material having a polymer matrix with hollow filler material that is dispersed and/or distributed within the polymer matrix. According to examples disclosed herein, the composite material is applied to and/or integrated with a semiconductor device. In turn, the hollow filler material includes and/or defines voids of the composite material. For example, the voids can be defined by spheroid or sphere-like structures with respective hollow voids within. The composite material can be integral with a portion/component of the semiconductor device (e.g., a substrate of the semiconductor device) or can be applied to portions of the semiconductor device (e.g., applied to cover exterior or internal surfaces of the semiconductor device).

According to some examples disclosed herein, the composite material is provided to the semiconductor device by placement, lamination, molding (e.g., overmolding), dispensing, layer deposition, etc. Additionally or alternatively, the composite material can be applied to the semiconductor device as an encapsulant or as a material included in a substrate or interposer, for example. In some examples, the composite material is molded into a component of the semiconductor device. According to examples disclosed herein, the encapsulant can be applied as an overmold, a mold, an underfill (e.g., an underfill that utilizes capillary action), an overfill and/or a buildup layer.

In some examples, the aforementioned composite material is utilized with a semiconductor device that includes a glass core. In some examples, the composite material is implemented as an encapsulant of a semiconductor device having multiple process dies, such as a multi-chip module (MCM), for example. Additionally or alternatively, the composite material at least partially defines a photo imagable dielectric (PID) layer, a buildup structure or a solder resist. In some examples, the composite material is at least partially composed of silicon dioxide or aluminum oxide.

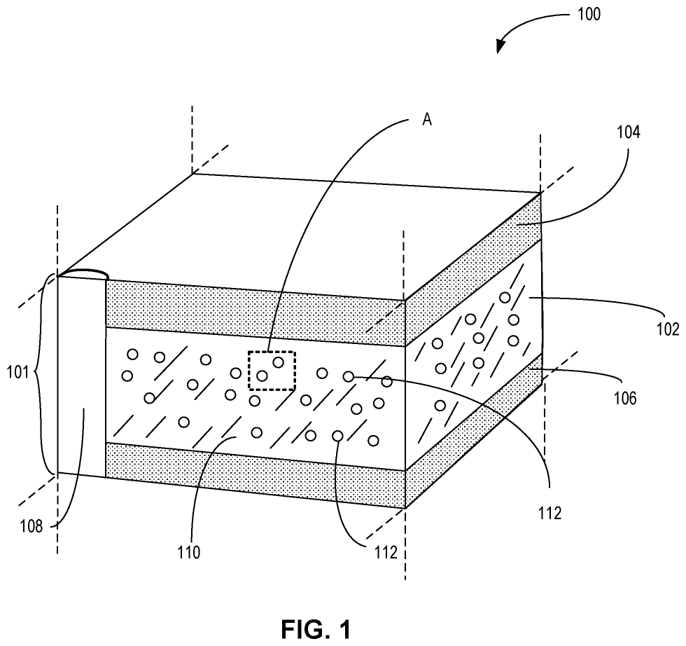

FIG. 1 is a cross-sectional cutaway view of an example semiconductor device (e.g., a semiconductor package, a processor device, a processor package, etc.) 100 with hollow filler material in accordance with teachings of this disclosure. The semiconductor device 100 of the illustrated example is generally structured in a layer construction 101 with a composite material 102 positioned between a first substrate (e.g., a first substrate layer) 104 and a second substrate (e.g., a second substrate layer) 106. Further, an example interconnect (e.g., a via, a trace, a means for electrically coupling, etc.) 108 is shown extending through the composite material 102, the first substrate 104 and the second substrate 108. In the illustrated example, the composite material (e.g., means for supporting means for reducing stress from displacement) 102 includes a polymer matrix 110 with hollow filler material (e.g., means for reducing stress from displacement) 112 distributed within.

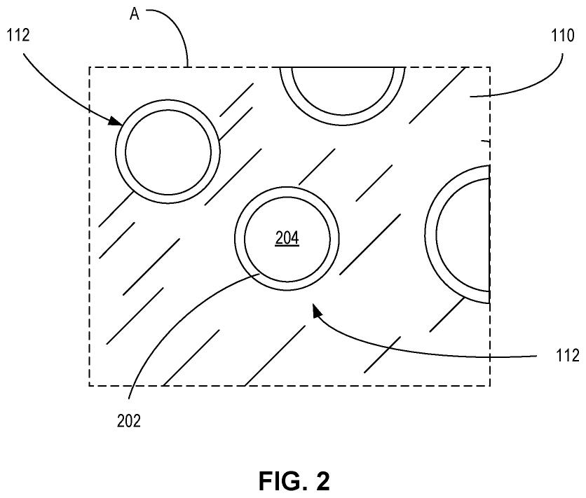

To significantly reduce a modulus of elasticity while not significantly impacting a CTE of the composite material 102 and/or the semiconductor device 100, the composite material 102 of the illustrated example includes the hollow filler material 112, which defines voids in the composite material 102. The example voids enable the composite material 102 to have a significantly reduced modulus. As will be discussed in greater detail below in connection with FIGS. 2-4, utilizing the hollow filler material 112 enables a relative low modulus without use of known additives that can cause relatively low toughness and adhesion. In other words, examples disclosed herein can be robust and highly resistant to damage that can be caused by excess movement and/or forces associated with the semiconductor device 100. As a result, examples disclosed herein can have increased service life and reliability. Further, examples disclosed herein can be implemented without any adverse effects to parameters, such as glass transition temperature, toughness, adhesion, etc.

In this example, the hollow filler material 112 is distributed throughout the composite material 102 in a relatively uniform manner (e.g., relatively uniform spacing throughout the composite material 102). However, in other examples, the hollow material 112 can be distributed throughout the composite material 102 in an uneven or irregular distribution (e.g., the hollow filler material 102 is distributed at a higher density in a particular region or side of the composite material 102 for localized relief and/or adjustment of the modulus). Additionally or alternatively, placement of the hollow material 112 is not generally reduced or eliminated near edges of the composite material 102.

While a layered construction is shown in the example of FIG. 1, any appropriate use of the composite material 102 can be implemented instead. In particular, the composite material 102 can be applied as a component (e.g., a produced component), an overmold, an underfill, a substrate, an encapsulant, and/or a mold, etc. In some examples, the hollow filler material 112 is at least partially composed of silicon dioxide. Additionally or alternatively, the hollow filler material 112 is at least partially composed of aluminum oxide. However, any appropriate material can be implemented instead.

FIG. 2 is a detailed view of a region A of the example semiconductor device 100 shown in FIG. 1. In the illustrated example of FIG. 2, the hollow filler material 112 is shown interspersed in and/or distributed within the polymer matrix 110. Further, the example hollow filler material 112 defines spheroid-shaped hollow structures, each of which includes a shell 202 with a respective void 204 disposed within. In this example, each of the shells 202 are sized in a range from approximately 300 nanometers (nm) to 700 (nm) (e.g., 500 nm). However, any appropriate size and/or scale pertaining to the shells 202 can be implemented instead. Further, the example shells 202 are relatively uniform in size (e.g., less than a 10% difference in diameter or outer dimensional sizes). However, in other examples, the sizes of the shells 202 may vary across the composite material 102 (e.g., the sizes of the shells 202 vary along a length of the composite material 102).

While the example hollow filler material 112 of FIG. 2 utilizes sphere-shaped or sphere-like structures, examples disclosed herein can utilize any appropriate structure with a corresponding void including, but not limited to, hollow oblong structures, hollow oval structures, hollow rectangular structures, hollow ellipsoid structures, etc. The thickness of the shells 202 and, thus, the volumetric size of the corresponding voids 204 can vary based on application-specific needs and/or design requirements. In some examples, a ratio of a thickness to an overall shell diameter is in a range from 0.05 to 0.30. However, the ratio can vary greatly between different applications.

The composite material 102 can be implemented as an applied/dispensed application or integrated within a component (e.g., a portion of the component) of the semiconductor device 100. For example, the composite material 102 can be part of a molded component of the semiconductor device 100. In some examples, different types of composite material (e.g., different polymer matrix materials) and/or hollow filler material are implemented on the same semiconductor device.

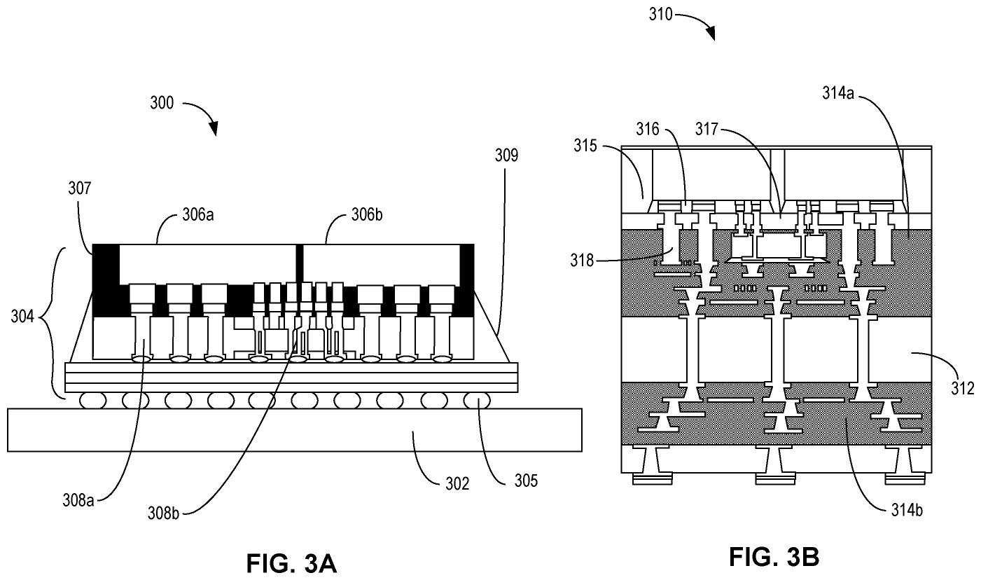

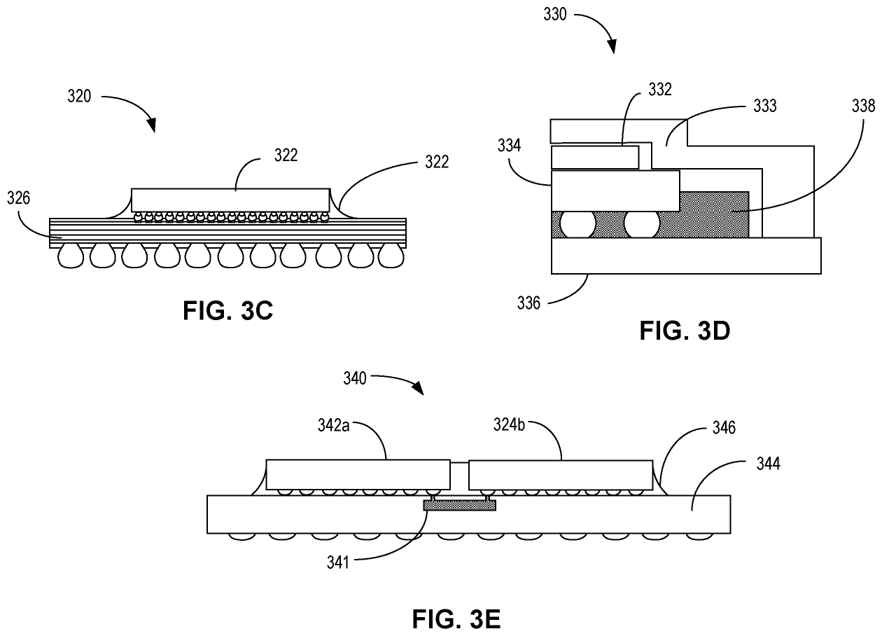

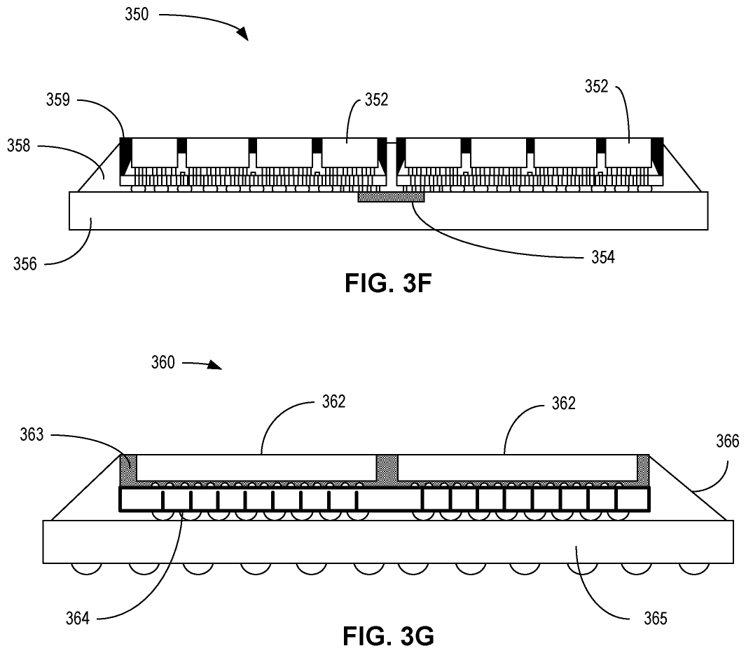

FIGS. 3A-3G depict example implementations in accordance with teachings of this disclosure. Turning to FIG. 3A, an example multi-die device (e.g., a processor package, a multi-die r package) 300 is shown attached to a substrate 302. The substrate 302 of the illustrated example supports an integrated circuit (IC) package 304 via contacts (e.g., ball grid array contacts) 305. In turn, the example IC package 304 includes dies (e.g., processor dies, memory dies, etc.) 306a, 306b (e.g., first and second means for computing), each of which are supported and/or positioned by a mold (e.g., a molded structure) 307. Further, interconnects 308a electrically couple the dies 306a, 306b with the substrate 302 while a bridge die 308b electrically couples the dies 306a, 306b together. In this example, an underfill 309 that contacts and/or is adjacent with the mold 307 is also implemented. Any of the mold 307, the underfill 309 and/or the substrate 302 can include the composite material 102. In other words, any of the mold 307, the underfill 309 and/or the substrate 302 can include the hollow filler material 112 surrounded by a polymer matrix (e.g., the polymer matrix 110). Further, the polymer matrix of each of the mold 307, the underfill 309 and/or the substrate 302, as well as structures defining the voids within, can be different composite material structures or materials, for example. In other words, different ones of the components of the semiconductor device 300 can have differing implementations of composite materials with hollow filler material.

FIG. 3B depicts an example glass core semiconductor device 310 in accordance with teachings of this disclosure. In the illustrated example of FIG. 3B, the glass core semiconductor device 310 includes a glass core 312 that is surrounded by buildup layer(s) 314a on a first side and buildup layer(s) 314b on a second side opposite to that of the first side. Further, the example glass core semiconductor device 310 includes a mold 315, a capillary underfill (CUF) 316, a solder resist/PID layer 317, and interconnects 318. In this example, the interconnects 318 extend through the buildup layer(s) 314a, the buildup layer(s) 314b, the glass core 312, the solder resist/PID layer 317, and the CUF 316. According to the illustrated example, the mold 315, the CUF 316, the solder resist/PID layer 317, the buildup 314a and/or the buildup 314b can be implemented with (e.g., at least partially composed of) the composite material 102.

FIG. 3C depicts an example flip chip semiconductor device 320 with a die 322. In this example, the composite material 102 can be implemented in an underfill 324 and/or a substrate 326.

Turning to FIG. 3D, an example path on interposer (PoINT) semiconductor device 330 is shown. In this example the semiconductor device 330 includes a die 332, an integrated heat spreader 333, a patch 334 on which the die 332 is positioned, and an interposer 336. According to examples disclosed herein, the composite material 102 can be implemented as an underfill between the die 332 and the patch 334 and/or between the patch 334 and the interposer 336, as shown by a region 338). Additionally or alternatively, the patch 334 and/or the interposer 336 can include the composite material 102. In some examples, an area within the integrated heat spreader 333 includes the composite material 102.

FIG. 3E depicts an example semiconductor device 340 with an embedded multi-die interconnect bridge (EMIB) 341. In this example, a die 342a and a second die 342b are mounted to a substrate 344. In this example, the composite material 102 is implemented in an encapsulant or overmold 346 that at least partially covers and/or surrounds the first die 342a and the second die 342b.

Turning to FIG. 3F, another example EMIB semiconductor device 350 is shown. The EMIB semiconductor device 350 of the illustrated example includes a plurality of dies 352 separated in different groupings that are linked by an EMIB 354 that is positioned in a substrate 356 in this example. Further, the example EMIB semiconductor device 350 includes an underfill 358, as well as a mold 359. The example composite material 102 can be implemented in the underfill 358, the mold 359 and/or the substrate 356.

FIG. 3G illustrates an example silicon interposer device 360, which includes dies 362 positioned in a mold 363 and adjacent an interposer 364 which, in turn, is positioned on a substrate 365. Further, an encapsulant 366 covers at least a portion of the example silicon interposer device 360. According to examples disclosed herein, the example composite material 102 can be implemented in the encapsulant 366 and/or the substrate 365.

Any feature or aspects of the examples shown in FIGS. 1-3G can be combined or used with other examples shown in FIGS. 1-3G. In other words, none of the features and/or aspects shown in FIGS. 1-3G are necessarily exclusive to those shown in connection with specific examples.

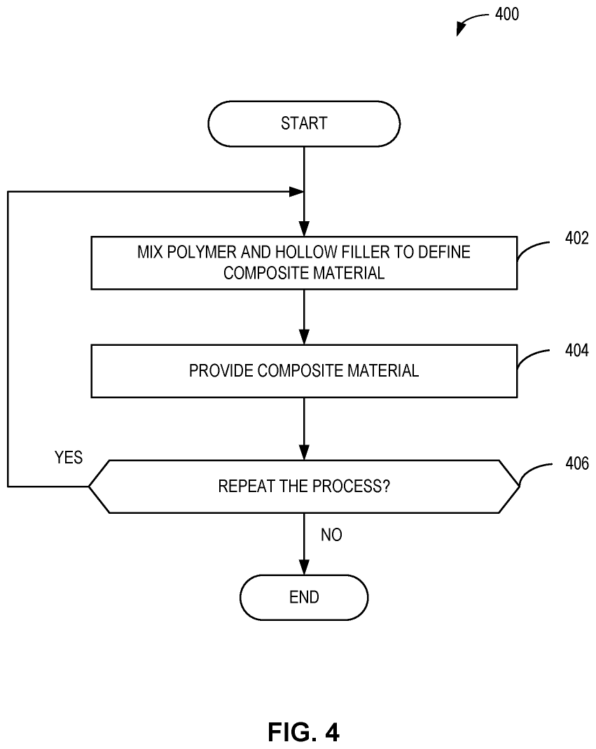

FIG. 4 is a flowchart representative of an example method 400 to produce examples disclosed herein. In this example, a semiconductor device (e.g., the device 100, the device 300, the device 310, the device, 320, the device 330, the device 340, the device 350, the device 360) is to be provided with the composite material 102.

At block 402, the polymer matrix 110 is provided with the hollow filler material 112 to define the composite material 102. In some examples, the hollow filler material 112 is mixed with the polymer matrix 110. In some examples, the polymer matrix 110 and/or the hollow filler material 112 includes an epoxy material. In some examples, a distribution of the hollow filler material 112 is controlled. In particular, a density and/or spacing of spheroid structures of the composite material 102 may be varied across a volume and/or length of the composite material 102, for example.

At block 404, in the illustrated example, the composite material 102 is provided to the semiconductor device. The composite material 102 may be molded, dispensed, deposited and/or coated to cover at least a portion of the semiconductor device. In some examples, the composite material 102 is deposited and/or laminated as layers (e.g., to produce a buildup structure). Additionally or alternatively, the composite material 102 is dispensed onto the semiconductor device (e.g., in a liquid or uncured form). In some examples, spheroids of the hollow filler material 112 are provided to the polymer matrix 110 (e.g., the spheroids are mixed with the polymer matrix 110). In some examples, the composite material 102 is cured subsequent to being provided to the semiconductor device.

At block 406, it is determined whether to repeat the process. If the process is to be repeated (block 406), control of the process returns to block 402. Otherwise, the process ends. This determination may be based on whether additional semiconductor devices are to be provided with the example composite material 102.

From the foregoing, it will be appreciated that example systems, methods, apparatus, and articles of manufacture have been disclosed that enable highly robust semiconductor devices that can be resistant to warpage, damage and/or malfunction from bending or other movements. Examples disclosed herein can also have similar and/or comparable CTEs to those of bulk polymer material while maintaining a relatively high degree of resistance to damage from that of the bulk polymer material.

Example methods, apparatus, systems, and articles of manufacture to semiconductor devices with hollow filler material are disclosed herein. Further examples and combinations thereof include the following:

Example 1 includes a semiconductor device comprising at least one of a substrate or an interposer, interconnects extending through the at least one of the substrate or the interposer, and a composite material integral with or covering at least a portion of the semiconductor device, the composite material including a polymer matrix with a hollow filler material having voids therein.

Example 2 includes the semiconductor device of example 1, wherein the voids are hollow interiors of spheroids of the hollow filler material.

Example 3 includes the semiconductor device of example 1, wherein the hollow filler material includes at least one of silicon dioxide or aluminum oxide.

Example 4 includes the semiconductor device of example 1, further including a die at least partially covered by the composite material.

Example 5 includes the semiconductor device of example 1, wherein the composite material is part of the at least one of the substrate or the interposer.

Example 6 includes the semiconductor device of example 1, wherein the composite material defines an underfill of the semiconductor device.

Example 7 includes the semiconductor device of example 1, wherein the composite material defines an encapsulant of the semiconductor device.

Example 8 includes the semiconductor device of example 1, wherein the composite material is part of a photo imagable dielectric layer of the semiconductor device.

Example 9 includes the semiconductor device of example 1, further including a glass core.

Example 10 includes an integrated circuit package comprising a die, interconnects electrically coupled to the die, and a composite material at least partially surrounding the die, the composite material including a polymer matrix with a hollow filler material having voids therein.

Example 11 includes the integrated circuit package of example 10, further including an embedded multi-die interconnect bridge.

Example 12 includes the integrated circuit package of example 10, further including a glass core.

Example 13 includes the integrated circuit package of example 10, wherein the die is a first die, and further including a second die, the second die at least partially surrounded by the composite material.

Example 14 includes the integrated circuit package of example 13, wherein the composite material defines an encapsulant that covers the first die and the second die.

Example 15 includes the integrated circuit package of example 10, wherein the composite material defines an underfill or an encapsulant of the integrated circuit package.

Example 16 includes the integrated circuit package of example 10, wherein the composite material is part of a photo imagable dielectric layer of the integrated circuit package.

Example 17 includes a method comprising providing a polymer matrix with a hollow filler material having voids therein to define a composite material, and applying the composite material to a semiconductor device to cover at least a portion of the semiconductor device.

Example 18 includes the method of example 17, wherein the providing the polymer matrix with the hollow filler material includes providing hollow spheroids to the polymer matrix.

Example 19 includes the method of example 17, wherein the applying the composite material to the semiconductor device includes laminating the composite material onto at least a portion of the semiconductor device.

Example 20 includes the method of example 17, wherein the applying the composite material to a semiconductor device includes molding the composite material onto at least a portion of the semiconductor device.

Example 21 includes a semiconductor device comprising means for electrically coupling, means for reducing stress from displacement, and means for supporting the means for reducing stress from displacement.

Example 22 includes the semiconductor device of example 20, further including first means for computing, and second means for computing.

Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

The following claims are hereby incorporated into this Detailed Description by this reference, with each claim standing on its own as a separate embodiment of the present disclosure.

What is claimed is:

1. A semiconductor device comprising:
at least one of a substrate or an interposer;
interconnects extending through the at least one of the substrate or the interposer; and
a composite material integral with or covering at least a portion of the semiconductor device, the composite material including a polymer matrix with a hollow filler material having voids therein.

2. The semiconductor device of claim 1, wherein the voids are hollow interiors of spheroids of the hollow filler material.

3. The semiconductor device of claim 1, wherein the hollow filler material includes at least one of silicon dioxide or aluminum oxide.

4. The semiconductor device of claim 1, further including a die at least partially covered by the composite material.

5. The semiconductor device of claim 1, wherein the composite material is part of the at least one of the substrate or the interposer.

6. The semiconductor device of claim 1, wherein the composite material defines an underfill of the semiconductor device.

7. The semiconductor device of claim 1, wherein the composite material defines an encapsulant of the semiconductor device.

8. The semiconductor device of claim 1, wherein the composite material is part of a photo imagable dielectric layer of the semiconductor device.

9. The semiconductor device of claim 1, further including a glass core.

10. An integrated circuit package comprising:
a die;
interconnects electrically coupled to the die; and
a composite material at least partially surrounding the die, the composite material including a polymer matrix with a hollow filler material having voids therein.

11. The integrated circuit package of claim 10, further including an embedded multi-die interconnect bridge.

12. The integrated circuit package of claim 10, further including a glass core.

13. The integrated circuit package of claim 10, wherein the die is a first die, and further including a second die, the second die at least partially surrounded by the composite material.

14. The integrated circuit package of claim 13, wherein the composite material defines an encapsulant that covers the first die and the second die.

15. The integrated circuit package of claim 10, wherein the composite material defines an underfill or an encapsulant of the integrated circuit package.

16. The integrated circuit package of claim 10, wherein the composite material is part of a photo imagable dielectric layer of the integrated circuit package.

17. A method comprising:
providing a polymer matrix with a hollow filler material having voids therein to define a composite material; and
applying the composite material to a semiconductor device to cover at least a portion of the semiconductor device.

18. The method of claim 17, wherein the providing the polymer matrix with the hollow filler material includes providing hollow spheroids to the polymer matrix.

19. The method of claim 17, wherein the applying the composite material to the semiconductor device includes laminating the composite material onto at least a portion of the semiconductor device.

20. The method of claim 17, wherein the applying the composite material to a semiconductor device includes molding the composite material onto at least a portion of the semiconductor device.

21. A semiconductor device comprising:
means for electrically coupling;
means for reducing stress from displacement; and
means for supporting the means for reducing stress from displacement.

22. The semiconductor device of claim 21, further including:
first means for computing; and
second means for computing.
